(19) United States
(12) Patent Application Publication
(10) Pub. No.: US 2015/0170988 A1
(43) Pub. Date: Jun. 18, 2015

(54) METHOD OF MANUFACTURING SEMICONDUCTOR APPARATUS

(71) Applicant: KABUSHIKI KAISHA TOSHIBA, Tokyo (JP)

(72) Inventors: Takeshi WATANABE, Yokkaichi Mie (JP); Takashi IMOTO, Kamakura Kanagawa (JP); Yuusuke TAKANO, Yokkaichi Mie (JP); Soichi HOMMA, Yokkaichi Mie (JP); Katsunori SHIBUYA, Kawagoe Mie (JP)

(21) Appl. No.: 14/474,670

(22) Filed: Sep. 2, 2014

(30) Foreign Application Priority Data
Dec. 13, 2013 (JP) 2013-258660

(51) Int. Cl. H01L 23/31; H01L 21/56; H01L 23/552

(52) U.S. Cl. CPC H01L 23/3142; H01L 23/552; H01L 21/56

(57) ABSTRACT

According to one embodiment, a plurality of semiconductor devices is mounted on a wiring substrate. A surface, on which a semiconductor devices of the wiring substrate are mounted, and the plurality of semiconductor devices are sealed by using a sealing resin. The wiring substrate which is sealed is cut and thus separated into semiconductor apparatuses. The semiconductor apparatuses after the separation are heated. A shield layer is formed by metal sputtering over wiring exposed at the edge of the cut wiring substrate and the sealing resin of the semiconductor apparatus, after the heating.

### CROSS-REFERENCE TO RELATED APPLICATION

This application is based upon and claims the benefit of priority from Japanese Patent Application No. 2013-258660, filed Dec. 13, 2013, the entire contents of which are incorporated herein by reference.

### FIELD

Embodiments described herein relate generally to a method of manufacturing a semiconductor apparatus.

### BACKGROUND

Recently, in portable wireless communication apparatuses such as cellular phones, suppression or avoidance of electromagnetic noise generated from embedded electronic components is required to avoid interference with a wireless system. Therefore, shielding of the electronic component which is a noise source has been studied. As a measure thereof, providing a shield layer by using a metal film on a surface of a semiconductor package sealed with a resin has been developed. But there remains the issue of the shield layer having satisfactory adhesive properties with the surface of the sealing resin formed over the embedded electronic component of the device.

### DESCRIPTION OF THE DRAWINGS

FIG. 1 is a cross-sectional view illustrating a structure of a semiconductor apparatus according to an embodiment.

FIG. 2 is a flow chart illustrating a process of manufacturing the semiconductor apparatus according to the embodiment.

FIG. 3 is a diagram illustrating growth of an oxidized film in a baking process of a semiconductor apparatus according to the embodiment.

FIG. 4 is a diagram illustrating a structure of an undersurface of the semiconductor apparatus according to the embodiment.

### DETAILED DESCRIPTION

The embodiment provides a method of manufacturing a semiconductor apparatus including satisfactory adhesive properties on a resin surface thereof for secure attachment of a shield layer thereover.

In general, according to one embodiment, a plurality of semiconductor devices are mounted on a surface of a wiring substrate and the plurality of semiconductor devices are sealed with a sealing resin formed thereover. The wiring substrates and resin sealing layer thereon is cut and thus separated into individual semiconductor apparatuses, and thereafter the individual semiconductor apparatuses are heated. A shield layer is then formed, by metal sputtering, on the edge portion of the cut wiring substrate and the surfaces of the sealing resin of the semiconductor apparatus after the heating is performed.

Hereinafter, exemplary embodiments are described with reference to the drawings. Further, indicating directions of upper, lower, left, and right directions in the embodiments and the drawings indicate relative directions when a surface on which external elements of a semiconductor apparatus are provided is set to be the bottom, and thus the descriptions of the directions may be different from directions of an actual device. In addition, for the convenience of explanation, the aspect ratios of the features illustrated in the drawings may be different from the aspect ratio thereof in an actual device.

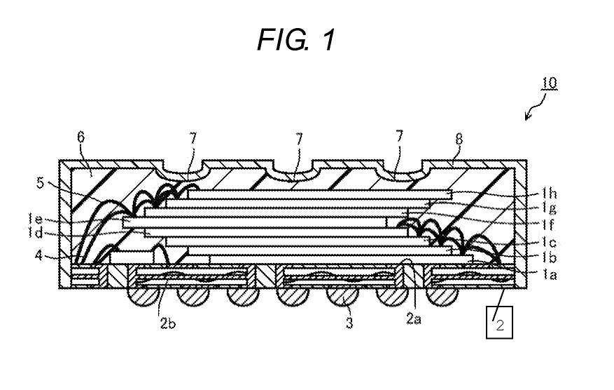

FIG. 1 is a cross-sectional view illustrating a structure of a semiconductor apparatus according to an embodiment.

A semiconductor apparatus 10 illustrated in FIG. 1 is a so-called area array semiconductor apparatus. A plurality of semiconductor devices 1a, 1b, 1c, to 1h are stacked one above the other to form multiple chip layers on a wiring substrate 2. Further, in the embodiment shown in FIG. 1, the number of stacked semiconductor devices is eight, that is, eight semiconductor device chips are stacked one over the other. However, the number of stacked semiconductor devices is not particularly limited, and, for example, one (a single semiconductor device), two, five, sixteen, or thirty two layers of individual semiconductor device chips may be stacked one over the other. For example, a NAND-type flash memory may be used for the semiconductor device. Further, FIG. 1 illustrates NAND-type flash memories 1a to 1h and a NAND controller (no reference numeral), and the semiconductor apparatus 10 illustrated in FIG. 1 functions as a storage device such as an SSD.

All of the plurality of semiconductor devices 1a, 1b, 1c, to 1h are formed on and/or in semiconductor substrates such as silicon substrates. Meanwhile, the wiring substrate 2 is a multilayer wiring substrate composed of, for example, a resin substrate, a ceramic substrate, and a glass substrate, as a material of an insulating substrate. A general multilayer copper clad laminated sheet (multilayer printed wiring board) or the like may be used as the wiring substrate 2 to which a resin substrate is applied. The number of the wiring layers may be plural, that is, a multilayer copper clad laminated sheet including two or more (for example, 2, 3, or 4) wiring layers may be used. Further, FIG. 1 illustrates an example of using a three-layer copper clad laminated sheet including a three-layer wiring layer. An electrode pad for connection of the apparatus 10 to an exterior location or component is provided on the undersurface of the wiring substrate 2, and external electrodes 3 such as solder bumps are provided on at least some of the electrode pads.

The external electrodes 3 are arranged in a lattice (grid array) on the undersurface of the wiring substrate 2. Although FIG. 1 illustrates an example of using bump electrodes such as solder bumps as the external electrode 3, an electrode film, formed by plating or the like on the electrode pad, may be used as the external electrode 3.

In addition, a surface wiring layer 2a including a signal pattern and a ground pattern is provided on the top surface of the wiring substrate 2, and each of the semiconductor devices 1a, 1b, 1c, to 1h are connected to the signal pattern and the ground pattern through a signal line wire 4 and a ground wire 5, respectively. Furthermore, the surface wiring layer 2a including the signal pattern and the ground pattern and an inter-layer wiring layer 2b connected to the electrode pad on the external electrode 3 side are provided within the wiring substrate 2. Here, a pattern (for example, the ground pattern) of the inter-layer wiring layer 2b which is electrically connected to the shield layer extends to the side (exposed edge) surface of the wiring substrate 2. Also, a pattern from the surface wiring layer 2a which is electrically connected to the shield layer also extends to the side (exposed edge) surface of the wiring substrate 2.

A mold resin 6 is molded on the top surface of the wiring substrate 2 on which the plurality of semiconductor devices 1a, 1b, 1c, to 1h are mounted so as to coat the semiconductor devices 1a, 1b, 1c, to 1h, the surface wiring layer 2a provided on the top surface of the wiring substrate 2, and the signal line wire 4 and the ground wire 5 that connect the semiconductor devices 1a, 1b, 1c, to 1h with the surface wiring layer 2a. The mold resin 6 forms an insulating layer by sealing the semiconductor devices 1a, 1b, 1c, to 1h, the surface wiring layer 2a, the signal line wire 4, the ground wire 5, and any other component on the wiring substrate 2, and any exposed portions on the wiring layer 2a side of the wiring substrate. For example, an epoxy resin including filler such as silica may be used as the mold resin 6.

Product information such as the product number, the year of manufacture, and the manufacturing plant where the apparatus 10 was manufactured is engraved into the top surface of the mold resin 6 by irradiation thereof with a laser. Here, in FIG. 1, reference numeral 7 indicates a marking section formed by the engraving by the laser irradiation. Furthermore, a shield layer 8 is formed by sputtering metal on the entire surface of the mold resin 6 on which the engraving is performed, as well as the top surface and the side surfaces of the mold resin 6 together with the side surfaces of the wiring substrate 2 extending to the side (edge) surfaces of the mold resin 6. The shield layer 8 blocks electromagnetic noise mainly generated from the semiconductor devices 1a, 1b, 1c, to 1h. Accordingly, the shield layer 8 is electrically connected to a portion of the pattern (for example, the ground pattern) provided on the inner-layer wiring layer 2b of the wiring substrate 2 which extends to and is exposed on the side (edge) surface of the wiring substrate 2, so that the shielding property of the shield layer 8 is ensured.

The metal material that forms the shield layer 8 is not particularly limited, and for example, Cu, Ni, Cr, B, or a Ni alloy containing Co or W is used. In addition, the shield layer 8 may be a single layer or a stacked structure having multiple layers (for example, a Cu/Ni alloy or a Cu/SUS alloy, starting with copper at the mold resin 6 side of the shield layer 8).

Furthermore, the thickness of the shield layer 8 is not particularly limited, but in order to reduce the size and the thickness of the semiconductor apparatus 10, it is preferable to form the shield layer 8 as thin as possible, so long as it is continuous over the mold resin 6 and the edges of the wiring substrate 2. It is possible to enhance the visibility of the marking section 7 by providing a thin shield layer 8. That is, if the shield layer 8 is thickened, the depth of the engraving by the laser irradiation showing therethrough is decreased so that the visibility thereof is deteriorated. The deterioration of the visibility may be prevented by thinning the shield layer 8. However, if the shield layer 8 is too thin, the mechanical strength of the shield layer 8 is decreased, a portion of the shield layer 8 may peel off and thus the shielding property may be decreased. In view of the above, the shield layer 8 is preferably in the range of 0.1 μm to 8 μm.

According to the present embodiment, the depth of the engraving of the marking section 7 into the mold resin 8 is about 30 μm, and the shield layer 6 has a two-layer structure of a Cu layer having a thickness of 0.1 μm to 6.0 μm on the surface of the mold resin 8 and an SUS (stainless steel) layer having a thickness of 0.1 μm to 1.5 μm thereover. The connection resistance, with a cross section of the pattern electrically connected to the shield layer, may be suppressed by having the surface side of the mold resin 6 in direct contact with the Cu layer. The corrosion resistance, and visibility of the marking section 7 formed in the shield layer 8 may be enhanced by providing the SUS layer over the Cu layer.

Further, for the marking of the mold resin to form the marking section 7 by a laser, a YAG laser, a YVO4 (Yttrium Vanadate) laser or the like preferably forms and obtains the engraving having a small spot diameter and a depth of about 30 μm. According to the present embodiment, the YAG laser having a spot diameter of 0.1 mm is used.

Since the shield layer 8 is formed by metal sputtering on the surface of the mold resin 6 on which the marking section 7 was formed by the laser irradiation in the semiconductor apparatus according to the present embodiment, an increase in the size and the thickness of the apparatus is suppressed and the marking section 7 has excellent visibility and a highly reliable electromagnetic shielding property is provided.

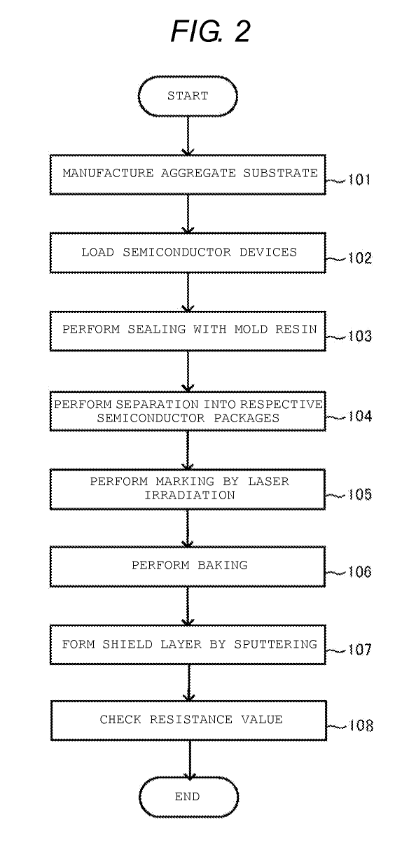

Subsequently, an example of a method of manufacturing the semiconductor apparatus 10 according to the embodiment is described with reference to the flowchart illustrated in FIG. 2.

As illustrated in FIG. 2, the method includes the following eight processes: manufacturing an aggregate substrate (Step 101), mounting semiconductor devices (Step 102) on the aggregate substrate, performing sealing with a mold resin (Step 103), performing separation of the aggregate substrate into respective semiconductor apparatuses (Step 104), performing marking by laser irradiation (Step 105), performing baking (Step 106), forming a shield layer by metal sputtering (Step 107), and checking the resistance value between the shield layer and the pattern electrically connected to the shield layer (Step 108).

First, in the manufacturing of the aggregate substrate in Step 101, the aggregate substrate having a structure in which the plurality of wiring substrates 2 are consecutively connected in a matrix shape is manufactured.

Subsequently, in the mounting of the semiconductor devices in Step 102, the semiconductor devices 1a, 1b, 1c, to ih are sequentially stacked on the top surface of each wiring substrate, and also the signal pattern and the ground pattern provided on the wiring substrate 2 are connected to each of the semiconductor devices 1a, 1b, 1c, to 1h respectively through the signal line wire 4 and the ground wire 5.

Subsequently, to seal with a mold resin in Step 103, the mold resin 6, for example, an epoxy resin is molded over the top surface side of the aggregate substrate (the wiring substrate from which individual apparatuses will be cut) on which the semiconductor devices 1a, 1b, 1c, to 1h are mounted so that the semiconductor devices 1a, 1b, 1c, to 1h are sealed therein. A molding method such as a transfer molding method, a compression molding method, or an injection molding method may be used for the molding of the mold resin 6.

Subsequently, in the separation process in Step 104, in order to manufacture the respective semiconductor apparatuses 10, the mold resin 6 is cut together with the aggregate substrate to form the wiring substrates 2 on which the semiconductor devices 1a, 1b, 1c, to 1h are mounted. A blade such as a diamond blade may be used for the cutting. Further, when performing the cutting, pure water in which carbon dioxide gas is dissolved is supplied to a contact portion between the blade and the mold resin 6 or the aggregate substrate. This is performed in order to cool the blade and the mold resin 6 and the aggregate substrate, suppress the scattering of dust generated during the cutting, and reduce static charge generated during the cutting.

Subsequently, in the marking process in Step 105, product information such as the product name, the product number, the year of manufacture, and the manufacturing plant of manufacture of the device is engraved on the top surface of the mold resin 6 by irradiation with a laser by a laser marking apparatus including a YAG laser or the like. In view of the satisfactory visibility and workability, the depth of the engraving is preferably in the range of about 20 μm to 40 μm, more preferably in the range of about 25 μm to 35 μm, and most preferably in the range of about 30 μm.

Subsequently, in the baking process in Step 106, each of the semiconductor apparatuses 10 is heated (baked). In the separation process, since each of semiconductor apparatuses 10 is cleansed with pure water, the mold resin 6 or the wiring substrate 2 may be in a state in which moisture is absorbed therein or adhered thereto. If the mold resin 6 or the wiring substrate 2 is subjected to metal sputtering with moisture absorbed therein or adhered thereto, the sputtered metal layer may peel off from portions of the mold resin 6 or the wiring substrate 2. In order to suppress such peeling, before performing the metal sputtering of the shield layer 8 onto the mold resin 6, each of the semiconductor apparatuses 10 is baked for a predetermined time at a temperature of the boiling point of water or higher to cause the moisture absorption of the mold resin 6 or the wiring substrate 2 to be decreased.

As a result of cutting in the separation process in Step 104, the cross section of the line pattern which will be electrically connected to the shield layer to connect the shield layer 8 to a ground terminal of the device is exposed at the side (edge) surfaces of the wiring substrate 2. In the baking process in Step 106, if each of the semiconductor apparatuses 10 is held for a predetermined time at a temperature of the boiling point of water or higher (for example, 100° C. or higher in 1 atm), the exposed portion of the wiring pattern may be oxidized by the resin baking, and the contact resistance between the shield layer 8 and the wiring pattern electrically connected to the shield layer 8 will be relatively high.

Therefore, in the baking process in Step 106, in order to suppress the oxidization of the exposed portion of the wiring pattern, each of the semiconductor apparatuses 10 is held in a heated environment having an oxygen concentration lower than an ambient atmospheric oxygen concentration. For example, each of the semiconductor apparatuses 10 is heated in a thermostatic chamber (Anaerobic Temperature Oven) that is heated above the boiling point of water while purging the inside of the chamber with an inert gas (N2, CO2, or the like).

Specifically, an oxygen concentration in the oven, lower than the ambient atmospheric oxygen concentration, is preferably 1.0% or lower. As a result, the thickness of any oxidized film in the exposed portion of the pattern electrically connected to the shield layer 8 is less than 50 nm, which is required to properly connect the shield layer 8 to the wiring pattern and thus to ground and result in the desired electromagnetic shielding properties therefrom.

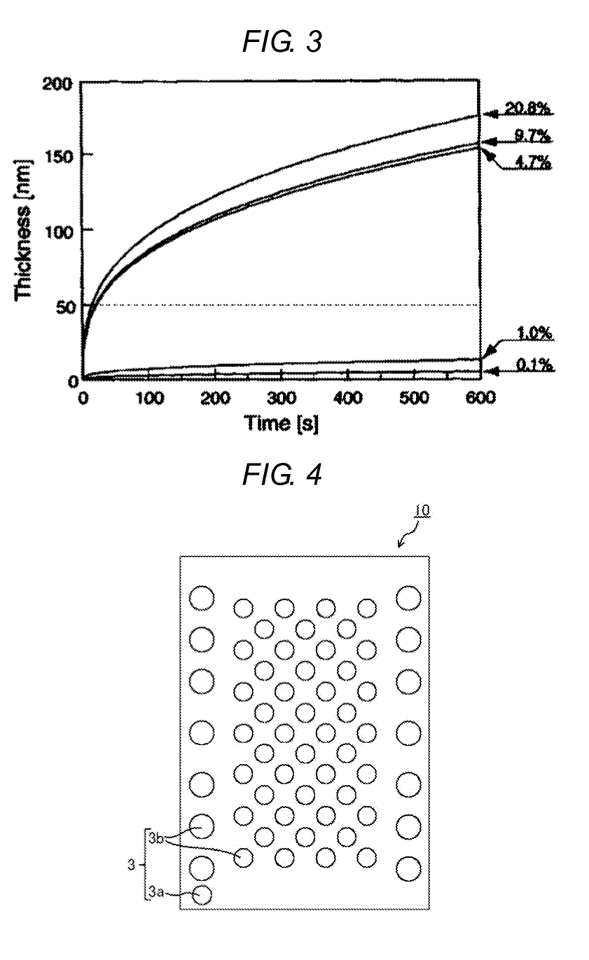

FIG. 3 is a graph illustrating growth of an oxidized film in a baking process of a semiconductor apparatus according to the embodiment. The horizontal axis represents the time period in which the semiconductor apparatus 10 is left in the thermostatic chamber (oven) in which the target baking temperature is set as 250° C. The vertical axis represents the thickness of the oxidized film on the exposed copper surfaces exposed at the edge of the substrate 2. Each of the curves represents growth of oxidized films at different oxygen concentrations in the oven. As illustrated in FIG. 3, when the oxygen concentration in the chamber is 1.0% or less, the baking time has little effect on the oxidized copper thickness after about 200 seconds, i.e., after 200 seconds of baking time further growth of the oxidized film is very slight. Accordingly, the oxygen concentration in the chamber is preferably 1.0% or lower. Here, if the semiconductor apparatus is baked at a temperature exceeding 250° C., since the mold resin 6 includes the epoxy resin or the phenol resin, the temperature will exceed a glass transition point of the mold resin 6. However, since the semiconductor apparatus need not be baked for a long period of time at more than 250° C., the baking temperature may be at or above 100° C. and at or below 250° C.

Subsequently, in the forming of the shield layer 8 by metal sputtering in Step 107, metal is sputtered onto the entire surface of the mold resin 6 on which the laser marking was performed, that is, all of the top surface and the side surfaces including the side surface (edges) of the exposed substrate 2, so that a shield layer 8 having a thickness of, for example, 3 μm is formed, forming a layer that conformally follows the contours of the laser marking and yielding the semiconductor apparatus 10 as illustrated in FIG. 1.

Further, when the metal sputtering is performed, it is preferable to roughen the surface, at least the top surface, of the mold resin 6, in advance to enhance the adhesive property of the shield layer 8 to the mold resin 6. In the present method, the mold resin sealing a number of underlying semiconductor apparatuses is cut in order to obtain multiple individual semiconductor apparatuses. Accordingly, since the side surface of the mold resin 6 is roughened by the cutting, an additional roughening of the mold resin 6 may not be required, but an additional roughening process may be added, if necessary. To further roughen the resin mold 6 surface, reverse sputtering (sputter etching) may be employed, i.e., before sputtering the metal layer, the surface of the resin mold 6 is sputtered by ions of the sputtering plasma, by negatively biasing the support on which the resin mold 6 and underlying substrate 2 are supported in the sputtering apparatus. If reverse sputtering is performed, it is not required to use another, for example a dedicated, etching apparatus to perform the roughening, but such a separate etching apparatus could be employed to sputter etch the resin mold 6 surface. In addition, since the roughening may be performed by using the same chamber as in the metal sputtering, the processes may be simplified and the processing time may be shortened. Therefore, roughening the surface of the resin mold by reverse sputtering is preferable.

Thereafter, in the inspection process in Step 108, the resistance value between the pattern electrically connected to the manufactured shield layer 8 of the semiconductor apparatus 10 and the shield layer 8 is measured. In the inspection process in Step 108, it is confirmed that there is no issue in the shielding property of the shield layer 8, i.e., the shield layer is adequately connected to the ground terminal, based on the resistance value.

FIG. 4 is a diagram illustrating an underside of the semiconductor apparatus 10 (as viewed from the external electrode 3 side). The external electrode 3 includes an external electrode 3a for measurement and a general external electrode 3b. The external electrode 3a for measurement is connected to the wiring pattern of the substrate electrically connected to the shield layer 8. In addition, a portion of the wiring pattern connected to the general external electrode 3b is also connected to the pattern electrically connected to the shield layer 8. However, the external electrode 3a for measurement and the general external electrodes 3b are not electrically connected through only the wiring pattern electrically connected to the shield layer 8, but electrically connected through both of the shield layer 8 and the wiring pattern electrically connected to the shield layer 8.

In the inspection process in step 108, the electrical resistance between the external electrode 3a for measurement and the portion of the general external electrode 3b connected to the wiring pattern electrically connected to the shield layer 8 is measured.

Further, in the present embodiment, a pad formed of the electrode film formed on the underside of the substrate 2 is used as the external electrode 3a for the measurement, and a bump electrode is used for the general external electrode 3b.

According to the aforementioned manufacture method of the semiconductor apparatus, since the shield layer is formed of sputtered metal, an extremely thin shield layer may be formed thereof, and the addition to the size and the thickness of the semiconductor apparatus may be minimized.

In addition, after the separation into respective semiconductor packages, the semiconductor apparatus 10 is heated before the metal sputtering. Accordingly, the sputtered metal layer may be suppressed from being peeled off, and a semiconductor having a good yield rate or yield percentage may be manufactured. Here, the heating of the semiconductor apparatus 10 before metal sputtering performed in an atmosphere having an oxygen concentration lower than the atmospheric oxygen concentration. Accordingly, the oxidization, or excess oxidation of the exposed surface of the pattern to be electrically connected to the shield layer 8 may be suppressed. As a result, the electrical resistance between the pattern electrically connected to the shield layer 8 and the shield layer 8 may be suppressed to be low.

Furthermore, after the product information or the like is marked into the surface of the mold resin 6 by the laser, the shield layer 8 is formed. Accordingly, a highly reliable shielding property may be obtained and also a marking section having sufficient visibility may be formed. That is, when laser marking is performed after forming the shield layer, the shield layer may be penetrated by the laser, and the shielding properties thereof may be decreased. In addition, if the shielding layer is not penetrated during marking, the engraving is shallow visibility thereof may not result. Since the shield layer is formed after the laser marking in the method of manufacturing the semiconductor apparatus, the shield layer may not be penetrated, and the engraving having a sufficient depth may be obtained. Accordingly, a highly reliable shield property may be obtained, and a marking section having sufficient visibility may be formed.

Furthermore, if laser marking is performed after the sputtering the metal to form the shield layer, since metal generally has high laser reflectance, the laser output has to be increased, and the life of the laser components are reduced and frequent exchanges and repairs are required. However, since the marking is performed on the mold resin that satisfactorily absorbs laser light in the method described above, the laser output may be lower, and frequent exchanges and repairs are not required, and a decrease in the manufacturing cost and an increase of the workability may be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor apparatus, the method comprising:
sealing a surface of a wiring substrate on which a plurality of semiconductor devices are mounted, and the plurality of semiconductor devices mounted thereon, with a sealing resin;
cutting the sealed wiring substrate into individual semiconductor apparatuses, wherein the edges of the portion of the wiring substrate thereof include exposed wire at the cut edge;
heating the semiconductor apparatuses after the separation thereof; and
covering the exposed edge of the wiring substrate and the sealing resin with a sputtered metal layer after the heating thereof.

2. The method according to claim 1,
wherein the semiconductor apparatus is heated in an atmosphere having an oxygen concentration lower than an atmospheric oxygen concentration.

3. The method according to claim 1, further comprising:
maintaining a heated environment for the heating of the semiconductor apparatus at an oxygen concentration of 1% or less.

4. The method according to claim 1, wherein the sputtered shield layer contains Cu.

5. The method according to claim 1, further comprising;
marking the sealing resin surface with a laser before forming the shield layer thereon.

6. The method according to claim 1, further comprising:
roughening the sealing resin before forming the shield layer thereof.

7. The method according claim 6, wherein the roughening of the sealing resin is accomplished by sputter etching the surface of the sealing resin in the same process environment where the sputtering of the metal to form the shield layer is performed.

8. The method according to claim 1, wherein the resin comprises epoxy or phenol resin, and the heating of the semiconductor apparatuses is performed above 100° C. and at or below 250° C.

9. The method according to claim 8, further including growing an oxidation layer on the surfaces of the portion of the wiring layer exposed at the edge of the semiconductor apparatuses of less than fifty microns thick.

10. A semiconductor apparatus, comprising;
a wiring substrate having a first side, a second side and a perimeter edge,
a metal layer formed on the first side and a metal layer formed on the second side, the metal layer on the first side extending to the edge of the wiring substrate;
one or more semiconductor device layers overlying the first side of the wiring substrate, at least one semiconductor device layer connected to the wiring layer on the first side;
a sealing resin overlying the semiconductor device layer and the first side of the wiring substrate, and extending to the edge of the wiring substrate;
a metal layer overlying the sealing resin and the edge of the wiring board; and
a contact region between at least a portion of the wiring layer of the first side of the wiring substrate and the metal layer, the contact region having an oxidized surface having a thickness of less than fifty microns.

11. The semiconductor apparatus of claim 10, wherein the oxidized surface is formed on the portion of the wiring layer on the first side of the wiring substrate located at the edge of the wiring substrate.

12. The semiconductor apparatus of claim 11, further comprising a contoured region extending into the sealing resin.

13. The semiconductor apparatus of claim 12, wherein the metal layer conformally extends into the contoured region of the sealing resin.

14. The semiconductor apparatus of claim 13, wherein the metal layer has a thickness of 0.1 micron or greater and 8.0 micron or less.

15. The semiconductor apparatus of claim 10, wherein
the sealing resin has an upper surface and a plurality of side surfaces contiguous with the edge of the wiring surfaces and extending from the side surfaces of the wiring substrate to the top surface; and
at least a portion of the side surface is mechanically roughened.

16. A semiconductor apparatus cut from a wiring board having at least a wiring layer formed on a first surface of the wiring board, one or more individual semiconductor based layers located on the wiring board, and a sealing resin layer formed over the wiring board and the semiconductor based layers, such that at least a portion of the wiring layer extends to the edge of the apparatus cut from the wiring board, the apparatus comprising
a metal layer overlying the cut sides of the sealing resin and edges of the cut wiring board; and
a contact region between at least a portion of the wiring layer and the metal layer, the contact region having an oxidized surface having a thickness of less than fifty microns.

17. The apparatus of claim 16, wherein the oxidized surface is located on the portion of the wiring layer at the end of the cut wiring board,

18. The apparatus of claim 17, wherein the sealing resin layer includes an identification pattern extending thereinto.

19. The apparatus of claim 18, wherein the metal layer conformally covers the identification pattern.

20. The apparatus of claim 19, wherein the metal layer electromagnetically shields the exterior of the apparatus from electromagnetic energy generated by the one or more individual semiconductor based layers.
